(19) United States
(12) Patent Application Publication
(10) Pub. No.: US 2026/0113899 A1
(43) Pub. Date: Apr. 23, 2026

(54) SERVER CABINET

(71) Applicant: Giga Computing Technology Co., Ltd., New Taipei City (TW)

(72) Inventor: Hamid Nalbandian Abhar, New Taipei City (TW)

(73) Assignee: Giga Computing Technology Co., Ltd., New Taipei City (TW)

(21) Appl. No.: 19/332,082

(22) Filed: Sep. 18, 2025

(30) Foreign Application Priority Data
Oct. 21, 2024 (TW) 113139870

(51) Int. Cl. H05K 7/20

(52) U.S. Cl. CPC H05K 7/20818; H05K 7/20736

(57) ABSTRACT

Provided is a server cabinet, which is adapted to be connected to a liquid cooling system. The server cabinet includes a cabinet, a heat exchanger, at least two sever racks, two partitions, a first fan assembly and a second fan assembly. The cabinet includes an internal space. The internal space is a sealed space. The heat exchanger is disposed in the internal space and has a first end and a second end opposite to each other. The at least two server racks are respectively disposed on opposite sides of the heat exchanger and have multiple heat sources. The two partitions are respectively disposed between one of the at least two server racks and the heat exchanger. The first fan assembly is disposed at the first end and generates an airflow. The second fan assembly is disposed at the second end.

### CROSS-REFERENCE TO RELATED APPLICATION

This application claims the priority benefit of Taiwan application serial no. 113139870, filed on October 21, 2024. The entirety of the above-mentioned patent application is hereby incorporated by reference herein and made a part of this specification.

### BACKGROUND

### Technical Field

The disclosure relates to a server cabinet, and particularly relates to a server cabinet having a sealed heat dissipation system.

### Related Art

Currently, large electronic equipment often needs multiple servers to provide operation. When the servers are operating, heat may be generated, which needs to instantly perform heat dissipation on the servers to avoid server failure due to high temperatures. Generally, the multiple servers may be disposed on arranged server racks. The server racks may be sequentially arranged in a server cabinet. The server cabinet may be in conjunction with a large cooling equipment therein to perform heat dissipation on the multiple servers. However, this type of server cabinet needs a large space. The cost may be higher for a smaller quantity of server racks. On the other hand, when the servers are cooled, fans may be used to directly discharge the heat generated during server operation out of a device, which is easy to cause thermal contamination to the environment.

### SUMMARY

The disclosure provides a server cabinet having a sealed heat dissipation system, which can perform heat dissipation on a server.

The server cabinet of the disclosure is adapted to be connected to a liquid cooling system. The server cabinet includes a cabinet, a heat exchanger, at least two server racks, two partitions, a first fan assembly, and a second fan assembly. The cabinet has an internal space. The internal space is a sealed space. The heat exchanger is disposed in the internal space and has a first end and a second end opposite to each other. The at least two server racks are respectively disposed on opposite sides of the heat exchanger. Each of the at least two server racks has multiple heat sources. The two partitions are respectively disposed between one of the at least two server racks and the heat exchanger. The first fan assembly is disposed at the first end. The first fan assembly generates an airflow. The airflow flows from the first fan assembly toward the at least two server racks. The second fan assembly is disposed at the second end. The airflow flows into the heat exchanger by the second fan assembly.

Based on the above, the disclosure provides the server cabinet that uses the heat exchanger and the partitions to directly allow the airflow generated by the first fan assembly to take away heat generated by the multiple heat sources on the server racks on both sides, and take back the airflow into the heat exchanger through the second fan assembly to perform heat dissipation. The airflow may not be dissipated from the internal space to the outside of the cabinet of the server cabinet, reducing thermal contamination generated during server operation.

In order to make the features and advantages of the disclosure more comprehensible, the following examples are given and described in detail with the accompanying drawings as follows.

### BRIEF DESCRIPTION OF THE DRAWINGS

FIG. 1 is a schematic view of a server cabinet according to the disclosure.

FIG. 2 is a top view of a server cabinet according to the disclosure.

FIG. 3 is a schematic view of partitions guiding an airflow according to the disclosure.

### DESCRIPTION OF THE EMBODIMENTS

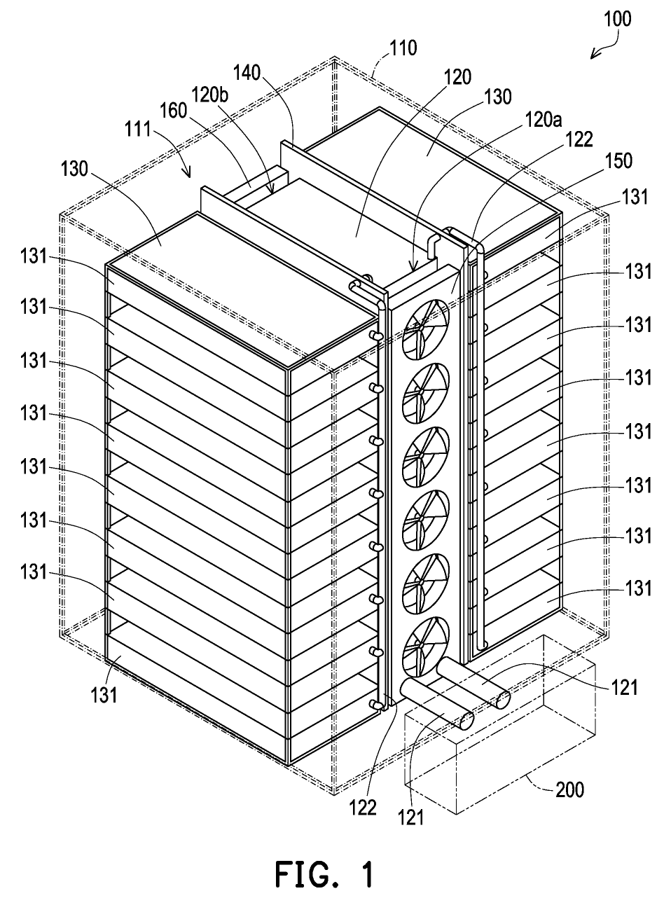

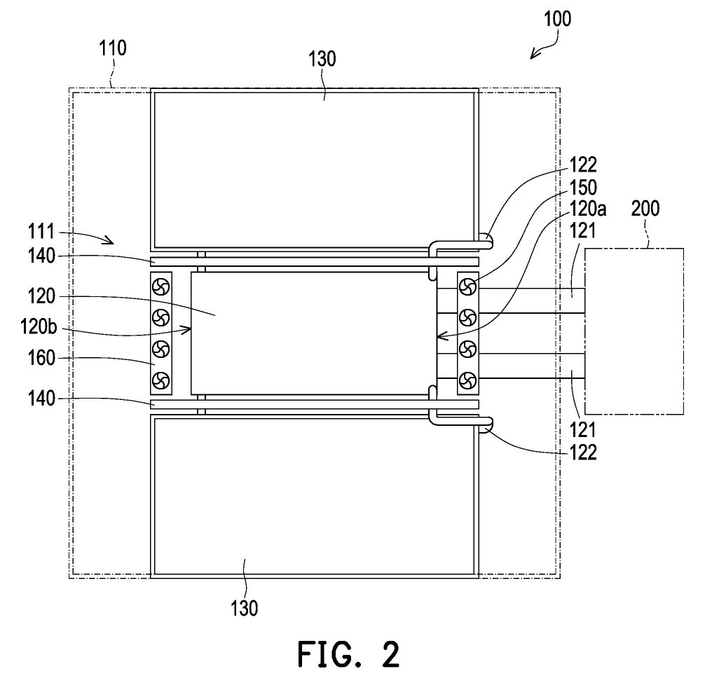

FIG. 1 is a schematic view of a server cabinet according to the disclosure. FIG. 2 is a top view of a server cabinet according to the disclosure. Please refer to FIG. 1 and FIG. 2 at the same time. In the embodiment, a server cabinet 100 is adapted to be connected to a liquid cooling system 200. The server cabinet 100 includes a cabinet 110, a heat exchanger 120, at least two server racks 130, two partitions 140, a first fan assembly 150, and a second fan assembly 160. The cabinet 110 has an internal space 111. The internal space 111 is a sealed space. The heat exchanger 120 is disposed in the internal space 111 and has a first end 120a and a second end 120b opposite to each other. The two server racks 130 are respectively disposed on opposite sides of the heat exchanger 120 and have multiple heat sources. The two partitions 140 are respectively disposed between one of the two server racks 130 and the heat exchanger 120. The first fan assembly 150 is disposed at the first end 120a. The second fan assembly 160 is disposed at the second end 120b.

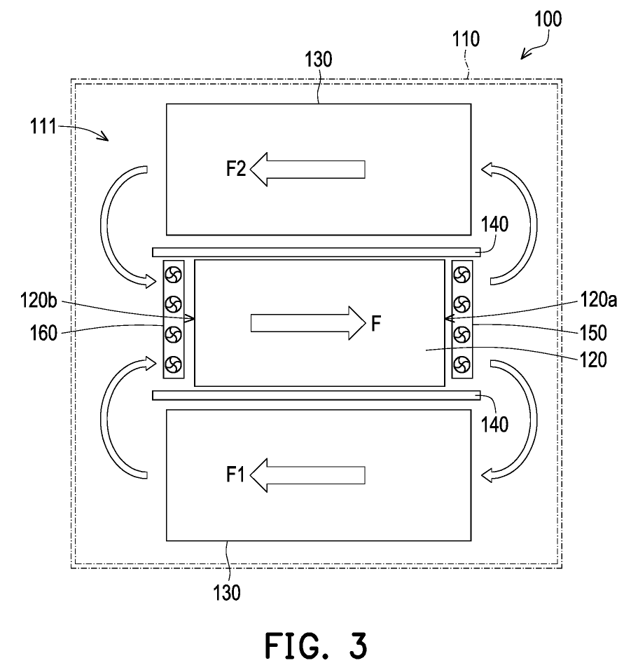

FIG. 3 is a schematic view of partitions guiding an airflow of the disclosure. Please refer to FIG. 2 and FIG. 3 at the same time. The first fan assembly 150 generates an airflow F. The airflow F flows from the first fan assembly 150 toward the two server racks 130, and flows into the heat exchanger 120 by the second fan assembly 160. In detail, the partition 140 extends from a bottom of the internal space 111 to a top of the internal space 111, and blocks the server rack 130 and the heat exchanger 120. That is to say, an orthogonal projection of the server rack 130 on a surface of the adjacent partition 140 may not exceed the partition 140, and an orthogonal projection of the heat exchanger 120 on the surface of the partition 140 may not exceed the partition 140. On the other hand, the airflow F respectively forms a first airflow F1 and a second airflow F2 after flowing through the two partitions 140. The first airflow F1 flows toward a direction of one of the two server racks 130. The second airflow F2 flows toward a direction of the other one of the two server racks 130. Since the two partitions 140 may each completely block the heat exchanger 120 and the two server racks 130, the first airflow F1 and the second airflow F2 may not be dissipated to the heat exchanger 120 when respectively flowing toward one of the two server racks 130. That is to say, the airflow F forms the first airflow F1 and the second airflow F2 by the two partitions 140, and respectively flows toward the direction of one of the two server racks 130. The first airflow F1 and the second airflow F2 may not intersect with each other and affect each other due to the blocking of the partition 140. In the embodiment, a quantity of the server racks 130 is two. In other embodiments, a quantity of the server racks 130 may also be four with two disposed on one side of the heat exchanger 120 and the other two disposed on the other side of the heat exchanger 120. There is also the partition 140 between adjacent server racks 130 so that the airflow F may not affect each other when flowing through the server racks 130. However, the disclosure is not limited thereto. In addition, in the embodiment, the two partitions 140 are made of a thermal insulating material, such as a plastic material. In other embodiments, the two partitions 140 may also be made of other non-metallic materials, as long as the partition 140 may resist high temperature and has poor thermal conductivity. However, the disclosure is not limited thereto.

Please refer to FIG. 1 and FIG. 3. Each of the server racks 130 has multiple servers 131 thereon. The servers 131 are regarded as heat sources of the server rack 130. The first airflow F1 and the second airflow F2 flow through the servers 131, so that heat generated by the servers 131 is taken away from the server rack 130, and enters the heat exchanger 120 by the second fan assembly 160. That is to say, the first airflow F1 and the second airflow F2 may take away a portion of the heat generated by the servers 131 when respectively flowing through the servers 131, and be transmitted into the heat exchanger 120 by the second fan assembly 160.

Following the above, the heat exchanger 120 further includes two heat exchange tubes 121. The two heat exchange tubes 121 are disposed at the first end 120a, and extend from the internal space 111 of the cabinet 110 to the outside of the cabinet 110 to be connected to the liquid cooling system 200. The two heat exchange tubes 121 have a working fluid therein, which is configured to transmit heat from the heat exchanger 120 to the liquid cooling system 200. In detail, the first airflow F1 and the second airflow F2 may transmit the heat into the heat exchanger 120 when entering the heat exchanger 120 by the second fan assembly 160 after respectively flowing through the two server racks 130. The heat is transmitted to the liquid cooling system 200 through one of the two heat exchange tubes 121, and then re-enters into the heat exchanger 120 by the other one of the two heat exchange tubes 121 after being cooled in the liquid cooling system 200. That is to say, the two heat exchange tubes 121 may transmit the heat in the heat exchanger 120 to the liquid cooling system 200 by the working fluid to perform cooling. The liquid cooling system 200 may be direct-to-chip liquid cooling.

Following the above, the heat exchanger 120 further has a cooling tube set 122, which is disposed in the heat exchanger 120. The cooling tube set 122 extends from the first end 120a out of the heat exchanger 120. The cooling tube set 122 also has a working fluid therein. In the embodiment, the cooling tube set 122 includes two pipes, which respectively extend from the heat exchanger 120 through the two adjacent partitions 140 toward the two server racks 130, and extend into the servers 131 to perform cooling on the servers 131. That is to say, the cooling tube set 122 transports the cooled working fluid from the first end 120a of the heat exchanger 120 into the multiple servers 131 on the server rack 130, and takes away the heat from the multiple servers 131. At this time, a temperature of the working fluid is increased. Then, the working fluid is transported back into the heat exchanger 120 through the second end 120b of the heat exchanger 120. The working fluid in the cooling tube set 122 is cooled in the heat exchanger 120.

In detail, the two partitions 140 are each connected to the top and the bottom of the internal space 111. The two partitions 140 respectively block the two server racks 130 and the heat exchanger 120. Therefore, the first airflow F1 and the second airflow F2 may not intersect with each other. The partitions 140 may effectively guide the direction of the first airflow F1 and the second airflow F2. Since the two partitions 140 respectively block the heat exchanger 120 and the adjacent server racks 130, the first airflow F1 and the second airflow F2 may not flow to the heat exchanger 120 when respectively flowing through the server racks 130, and may more effectively perform heat dissipation on the multiple servers 131.

Following the above, the first airflow F1 may flow to the second fan assembly 160 through a guidance of the partition 140 after flowing through the server rack 130. Similarly, the second airflow F2 may also flow to the second fan assembly 160 through a guidance of the partition 140 after flowing through the server rack 130. The first airflow F1 and the second airflow F2 are collected into the airflow F through the second fan assembly 160 and enter the heat exchanger 120 by the second fan assembly 160. When the airflow F taking heat enters the heat exchanger 120, the heat may be transmitted to the heat exchanger 120. In the embodiment, there are multiple fin sets and multiple heat pipes in the heat exchanger 120. The airflow F transmits the heat to the fin sets and the heat pipes, and transmits to the liquid cooling system 200 by the heat exchange tube 121. That is to say, after the airflow F taking the heat enters the heat exchanger 120 by the second fan assembly 160, the heat may be transmitted to the heat exchanger 120, so that the airflow F does not take the heat when flowing out of the heat exchanger 120 by the first fan assembly 150, and may effectively perform heat dissipation on the two server racks 130. In addition, directly connecting the cooling tube set 122 to the servers 131 may also take away another portion of the heat and transmit back to the heat exchanger 120 to perform cooling, so that the cooling tube set 122 does not take the heat when flowing out from the first end 120a of the heat exchanger 120 to effectively perform heat dissipation on the servers 131.

In summary, the server cabinet of the disclosure uses the heat exchanger and the partitions to directly allow the airflow generated by the first fan assembly to take away the heat generated by the multiple heat sources on the server racks on both sides, and takes the airflow back into the heat exchanger to perform heat dissipation through the second fan assembly. The airflow may not be dissipated from the internal space to the outside of the cabinet of the server cabinet, reducing thermal contamination generated during server operation.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

What is claimed is:

1. A server cabinet, adapted to be connected to a liquid cooling system, and the server cabinet comprising:
a cabinet, having an internal space, wherein the internal space is a sealed space;
a heat exchanger, disposed in the internal space and having a first end and a second end opposite to each other;
at least two server racks, respectively disposed on opposite sides of the heat exchanger, wherein each of the at least two server racks has a plurality of heat sources;
two partitions, respectively disposed between one of the at least two server racks and the heat exchanger;
a first fan assembly, disposed at the first end, wherein the first fan assembly generates an airflow, and the airflow flows from the first fan assembly toward the at least two server racks; and
a second fan assembly, disposed at the second end, wherein the airflow flows into the heat exchanger by the second fan assembly.

2. The server cabinet according to claim 1, wherein the heat exchanger further comprises two heat exchange tubes, wherein the two heat exchange tubes are disposed at the first end and extend to the outside of the cabinet to be connected to the liquid cooling system.

3. The server cabinet according to claim 1, wherein each of the two partitions extends from a bottom of the internal space to a top of the internal space and blocks one of the at least two server racks and the heat exchanger.

4. The server cabinet according to claim 3, wherein an orthogonal projection of each of the two partitions on a surface of the partitions does not exceed the partitions.

5. The server cabinet according to claim 1, wherein the airflow divides into a first airflow and a second airflow after flowing through the two partitions, the first airflow flows toward one of the at least two server racks, and the second airflow flows toward the other one of the at least two server racks.

6. The server cabinet according to claim 5, wherein the first airflow and the second airflow flow into the heat exchanger through the second fan assembly.

7. The server cabinet according to claim 5, wherein the first airflow and the second airflow are separated from each other by the two partitions.

8. The server cabinet according to claim 1, wherein the heat exchanger further comprises a cooling tube set disposed in the heat exchanger, extending from the first end out of the heat exchanger, extending through the two partitions toward the heat sources, and connected to the heat exchanger by the second end.

9. The server cabinet according to claim 1, wherein the two partitions are made of a thermal insulating material.
